(19) United States
(12) Patent Application Publication
(10) Pub. No.: US 2021/0199903 A1
(43) Pub. Date: Jul. 1, 2021

(54) OPTICAL COMMUNICATION MODULE OF REDUCED COMPLEXITY AND COST

(71) Applicant: SHUNSIN TECHNOLOGY (ZHONG SHAN) LIMITED, Zhongshan (CN)

(72) Inventor: JIE HUANG, Zhongshan City (CN)

(21) Appl. No.: 17/112,392

(22) Filed: Dec. 4, 2020

(30) Foreign Application Priority Data
Dec. 26, 2019 (CN) 201911370490.3

(51) Int. Cl. G02B 6/42; G02B 6/43

(52) U.S. Cl. CPC G02B 6/428; G02B 6/426; H01S 5/183; G02B 6/4243; G02B 6/43; G02B 6/4296

(57) ABSTRACT

A simple optical communication module with reduced number of components includes a circuit board; an optical-signal transmitter disposed on the circuit board, and having a light-emitting surface; an optical fiber having an incident end and a vertical segment connected to the incident end, wherein the incident end is adjacent to the light-emitting area of the light-emitting surface, and the vertical segment extends perpendicular to the light-emitting surface. A holding frame is disposed on the circuit board, and holds the vertical segment.

### FIELD

The present disclosure relates to an optical communications.

### BACKGROUND

Optical communications have low transmission loss, high data confidentiality, total immunity to electromagnetic interference (EMI), wide bandwidth, and is a major communication method today. The optical communication module is an important basic component in optical communication technology. The optical communication module receives optical signals and converts the optical signals into electrical signals. The optical communication module can also convert electrical signals into optical signals, and then transmit the optical signals outward.

The conventional optical communication module can use a vertical-cavity surface-emitting laser (VCSEL) for optical signals. In order to allow the beam emitted by VCSEL to enter the optical fiber, a lens is used to focus the beam, and then a reflective element is used to reflect the beam to the optical fiber. Therefore, more optical components such as lenses and reflective elements are required thereby, resulting in an increase of the manufacturing costs. In addition, the beam has a large power loss after passing through the lens and reflective elements, which affects the performance of the optical communication module.

### BRIEF DESCRIPTION OF THE DRAWINGS

Many aspects of the present disclosure are better understood with reference to the following drawings. The components in the drawings are not necessarily drawn to scale, the emphasis instead being placed upon clearly illustrating the principles of the present disclosure. It will be appreciated that for simplicity and clarity of illustration, where appropriate, reference numerals have been repeated among the different figures to indicate corresponding or analogous elements.

FIG. 1 is a schematic view of an optical communication module in accordance with an embodiment of the present disclosure.

FIG. 2 is a perspective view of an optical-signal transmitter and a holding frame of the optical communication module.

FIG. 3 is a side view of the optical-signal transmitter and the holding frame in FIG. 2.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The disclosure is illustrated by way of embodiments and not by way of limitation in the figures of the accompanying drawings, in which like references indicate similar elements. It should be noted that references to “an” or “one” embodiment in this disclosure are not necessarily to the same embodiment, and such references mean “at least one.”

The term “connected” is defined as directly or indirectly through intervening components. The connection can be such that the objects are permanently connected or releasably connected. The term “comprising,” when utilized, means “including, but not necessarily limited to”; it specifically indicates open-ended inclusion or membership in the so-described combination, group, series, and the like.

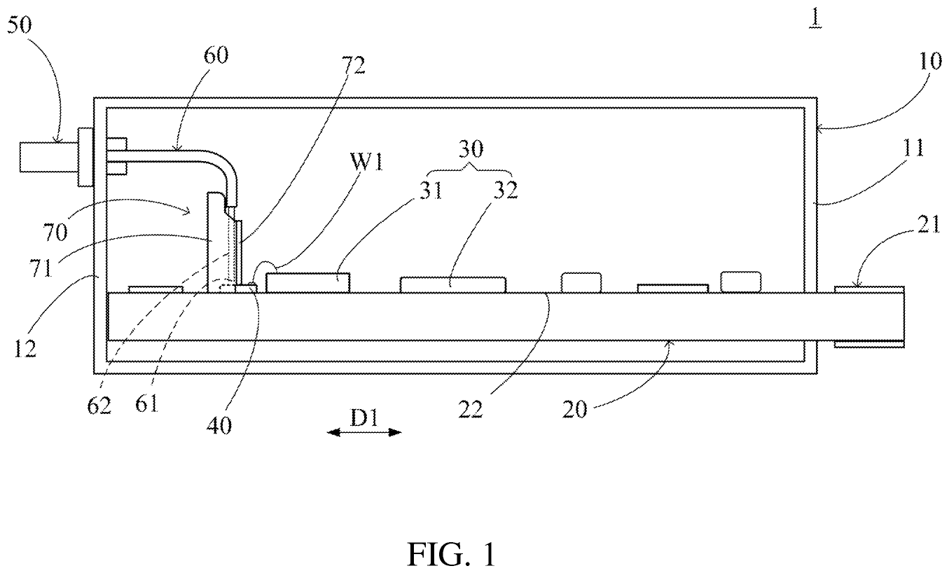

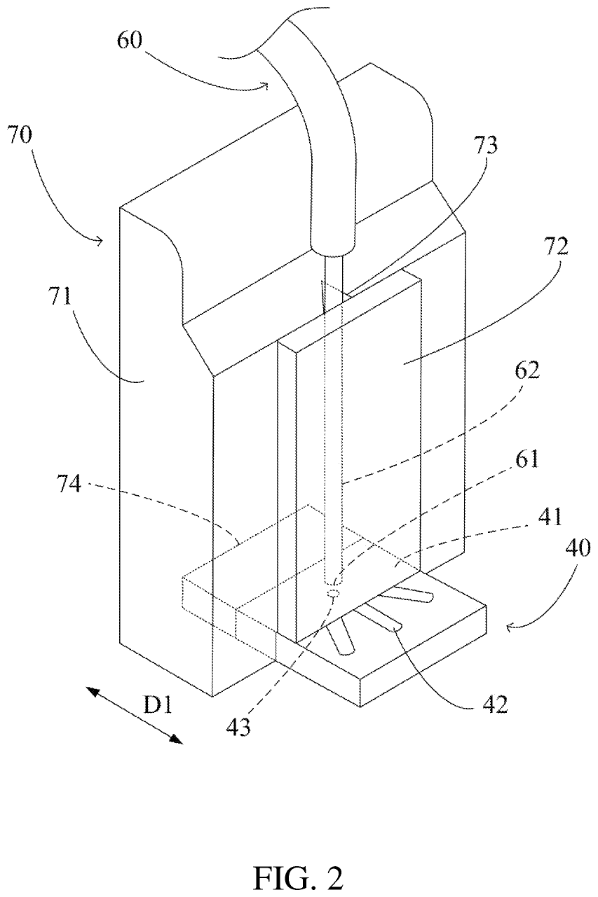

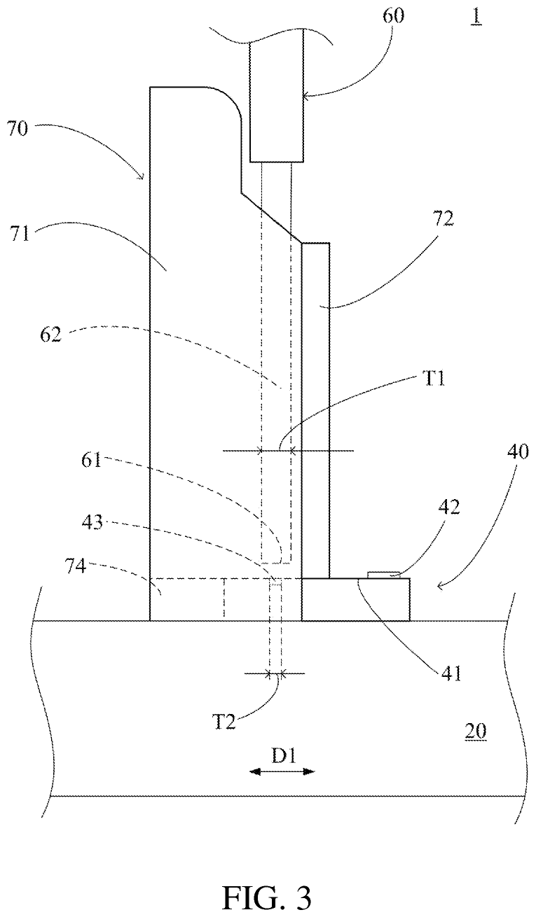

FIG. 1 is a schematic view of an optical communication module 1 in accordance with an embodiment of the present disclosure. FIG. 2 is a perspective view of an optical-signal transmitter 40 and a holding frame 70 of the optical communication module 1. FIG. 3 is a side view of the optical-signal transmitter 40 and the holding frame 70 in FIG. 2, wherein for the purpose of clarity, some elements are omitted. The optical communication module 1 can be installed in an electronic device (not shown in figures), so that the electronic device can transmit and receive optical signals. The electronic device can be a computer, a server, or a router, but is not limited thereto. The optical communication module 1 can be an optical transmitting module or an optical transceiver module. The optical transmitting module can receive electrical signals from the electronic device and convert the electrical signals to optical signals, and the optical signals can be transmitted out via an external optical fiber. The optical transceiver module can receives optical signals via the external optical fiber, convert the optical signals to electrical signals, and transmit the electrical signals to the electronic device. Moreover, the optical transceiver module can integrate the functions of the optical transmitting module into one device.

In the embodiment, the optical communication module 1 can be an optical transmitting module, but it is not limited thereto. The optical communication module 1 includes a metal housing 10, a circuit board 20, chips 30, an optical-signal transmitter 40, an optical-fiber connector 50, an optical fiber 60, and a holding frame 70. The metal housing 10 may be an elongated structure extending in an extension direction D1. The metal housing 10 covers and surrounds the circuit board 20, the chip 30, the optical-signal transmitter 40, and the holding frame 70. The metal housing 10 shields against EMI. In some embodiments, an enclosed and sealable space is formed inside the metal housing 10 to prevent water vapor or dust outside the metal housing 10 from entering the metal housing 10, thereby improving the service life and signal reliability of the optical communication module 1.

The circuit board 20 is disposed in the metal housing 10. The circuit board 20 may be an elongated structure extending in the extension direction D1. The circuit board 20 can be a rigid printed circuit board (Rigid PCB, RPC). The plug end 21 of the circuit board 20 passes through the side wall 11 of the metal housing 10. In other words, the plug end 21 of the circuit board 20 is exposed outside the metal housing 10. In the embodiment, the plug end 21 of the circuit board 20 is inserted into the electrical connector of the electronic device, so that the circuit board 20 can receive electrical signals from the electronic device via the plug end 21.

The chips 30 are located in the metal housing 10, and disposed on the circuit board 20. In the embodiment, the chips 30 can be mounted on the circuit board 20 by chip-on-board (COB) packaging or surface-mount technology (SMT). The chips 30 can be adhered on the upper surface 22 of the circuit board 20, electrically connected to the circuit board 20. The number and type of chips 30 is not limited.

For example, the chips 30 may include a drive chip 31 and a monitor photodiode (MPD) chip 30. The drive chip 31 can be electrically connected to the monitor photodiode chip 32 and the optical-signal transmitter 40. The drive chip 31 is configured to drive the optical-signal transmitter 40. In the embodiment, the drive chip 31 can drive the optical-signal transmitter 40 to generate a beam according to the electrical signals transmitted by the electronic device, so that the beam has optical signals. The MPD chip 32 can detect the power of the output beams L1 emitted by the optical-signal transmitter 40 and other characteristics.

The optical-signal transmitter 40 is in the metal housing 10, and disposed on the circuit board 20. In the embodiment, the optical-signal transmitter 40 can be affixed to the upper surface 22 of the circuit board 20 by glue. The optical-signal transmitter 40 can be electrically connected to the drive chip 31 via wire W1. The drive chip 31 controls the optical-signal transmitter 40 to emit the beam into the optical fiber 60 according to electrical signals. In the embodiment, the optical-signal transmitter 40 is a vertical-cavity surface-emitting Laser (VCSEL). The beam is a laser beam. In some embodiments, the optical-signal transmitter 40 is a light-emitting diode (LED).

As shown in FIG. 1 and FIG. 2, the optical-signal transmitter 40 includes a light-emitting surface 41 and conductive pads 42. The optical-signal transmitter 40 emits the beam through the light-emitting area 43 of the light-emitting surface 41 for entry into the optical fiber 60. The conductive pads 42 are disposed on the light-emitting surface 41, and the drive chip 31 is connected to the conductive pads 42 via the wire W1.

The optical-fiber connector 50 passes through the side wall 12 of the metal housing 10. In the embodiment, the side wall 12 is opposite to the side wall 11. In other words, the optical-fiber connector 50 and the plug end 21 of the circuit board 20 are at opposite sides of the metal housing 10. In the embodiment, the optical-fiber connector 50 is a receptacle. The optical-fiber connector 50 can be affixed to one end of the optical fiber 60, and connected to the external optical fiber, to align the external optical fiber with the optical fiber 60.

The optical fiber 60 is connected to the holding frame 70 and the optical-fiber connector 50. The optical fiber 60 has an incident end 61 and a vertical segment 62. The incident end 61 is adjacent to the light-emitting area 43 of the light-emitting surface 41. The vertical segment 62 is connected to the incident end 61, and extends perpendicular to the light-emitting surface 41. In some embodiments, the vertical segment 62 extends perpendicular to the extension direction D1.

As shown in FIG. 2 and FIG. 3, the optical fiber 60 is a multimode optical fiber. The diameter T1 of the vertical segment 62 is in a range from about 40 μm to 60 μm. The width T2 of the light-emitting area 43 is in a range from about 5 um to 10 um. For example, the diameter of the vertical segment 62 is about 50 μm. The width T2 of the light-emitting area 43 is about 7 μm or 8 μm. The diameter T1 of the vertical segment 62 is 2-5 times greater than the width T2 of the light-emitting area 43, diameter T1 and width T2 being measured in the same direction. In the embodiment, the diameter T1 and the width T2 are measured in the extension direction D1.

In the embodiment, the distance between the incident end 61 and the light-emitting area 43 is equal to or less than the diameter T1 of the vertical segment 62. Moreover, the distance between the incident end 61 and the light-emitting area 43 is less than 50 um. In some embodiments, the incident end 61 of the optical fiber 60 directly contacts the light-emitting area 43. In other words, there is no distance or gap between the incident end 61 and the light-emitting area 43.

Accordingly, in the optical communication module 1, the beam emitted by the optical-signal transmitter 40 can directly enter into the optical fiber 60 to reduce energy loss of the beam, thereby improving the performance of the optical communication module 1. Moreover, in the embodiment, no lens and/or reflective element is necessary between the light-emitting area 43 of the optical-signal transmitter 40 and the incident end 61 of the optical fiber 60, thereby reducing the manufacturing cost of the optical communication module 1.

The holding frame 70 is disposed on the circuit board 20, and affixed to the vertical segment 62 of the optical fiber 60. The holding frame 70 includes a holding body 71 and a cover 72. The holding body 71 is affixed to the circuit board 20, is perpendicular to the circuit board 20, and/or extends in the extension direction D1. In the embodiment, the holding body 71 is affixed to the circuit board 20 by glue. The holding body 71 has a V-shaped groove 73 (as shown in FIG. 2), extending perpendicular to the circuit board 20 and/or the extension direction D1.

In the embodiment, the holding body 71 further includes a receiving groove 74 on the bottom of the holding body 71. The V-shaped groove 73 can be connected to the receiving groove 74. A portion of the optical-signal transmitter 40 is in the receiving groove 74, and the light-emitting area 43 of the optical-signal transmitter 40 in the holding body 71 corresponds to the incident end 61 of the optical fiber 60. In some embodiments, a portion of the optical-signal transmitter 40 is fastened in the receiving groove 74, so that the holding frame 70 can be stably mounted on the circuit board 20 and the optical-signal transmitter 40.

The vertical segment 62 of the optical fiber 60 is in the V-shaped groove 73. The cover 72 is affixed to the holding body 71, and covers the V-shaped groove 73. In other words, the vertical segment 62 is affixed between the V-shaped groove 73 and the cover 72. Moreover, the cover 72 is above the light-emitting surface 41. In the embodiment, the cover 72 contacts or abuts against the light-emitting surface 41 of the optical-signal transmitter 40, so that the holding frame 70 can be firmly installed on the circuit board 20 and the optical-signal transmitter 40.

The holding frame 70 easily and stably sets the vertical segment 62 of the optical fiber 60 perpendicular to the light-emitting surface 41 of the optical-signal transmitter 40. Moreover, the V-shaped groove 73 reduces the area of the optical fiber 60 which is in contact the holding body 71, reducing the risk of the holding frame 70 interfering with the signal of the optical fiber 60.

In the embodiment, the holding body 71 and the cover 7 can be made of glass or ceramics. Since the expansion coefficient of the holding body 71 and the cover 72 is close to that of the optical fiber 60, physical interference (by misalignment or other) by the holding frame 70 with the transmission of beam to the optical fiber 60 is prevented.

In the optical communication module of the disclosure, the optical fiber is set by the holding frame in a very stable manner perpendicular to the optical-signal transmitter. The optical-signal transmitter can directly emit the beam into the optical fiber to reduce energy loss of the beam, thereby enhancing the performance of the optical communication module. In addition, the disclosed optical communication module does not need to include a lens and/or reflective element between the optical-signal transmitter and the optical fiber, thereby reducing the manufacturing cost of the optical communication module.

Many details are often found in the art of optical communication modules. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will, therefore, be appreciated that the embodiments described above may be modified within the scope of the claims.

What is claimed is:

1. An optical communication module, comprising:
a circuit board;
an optical-signal transmitter disposed on the circuit board, and comprises a light-emitting surface;
an optical fiber comprising an incident end, and a vertical segment connected to the incident end, wherein the incident end is adjacent to a light-emitting area of the light-emitting surface, and the vertical segment extends perpendicular to the light-emitting surface; and
a holding frame disposed on the circuit board, and holding the vertical segment.

2. The optical communication module as claimed in claim 1, wherein the optical-signal transmitter is a Vertical-Cavity Surface-Emitting Laser configured to emit a beam into the optical fiber via the light-emitting area, and the optical fiber is a multimode optical fiber.

3. The optical communication module as claimed in claim 1, wherein a diameter of the vertical segment is greater than two times a width of the light-emitting area, and the diameter and the width are measured in the same direction.

4. The optical communication module as claimed in claim 1, wherein a distance between the incident end and the light-emitting area is equal to or less than a diameter of the vertical segment.

5. The optical communication module as claimed in claim 1, wherein no lens is between the light-emitting area and the incident end.

6. The optical communication module as claimed in claim 1, wherein the holding frame comprises:
a holding body affixed to the circuit board, and comprises a V-shaped groove extending perpendicular to the circuit board; and
a cover covering to the V-shaped groove;
wherein the vertical segment is between the V-shaped groove and the cover.

7. The optical communication module as claimed in claim 6, wherein the cover is above the light-emitting surface, and the cover is glass.

8. The optical communication module as claimed in claim 1, further comprising:
a metal housing covering the circuit board, the optical-signal transmitter, and the holding frame; and
an optical-fiber connector extending through a side wall of the metal housing, and affixed to an end of the optical fiber.

9. The optical communication module as claimed in claim 1, further comprising:
a plurality of chips disposed on the circuit board, wherein the chips comprise a drive chip electrically connected to the optical-signal transmitter.

10. The optical communication module as claimed in claim 9, wherein the optical-signal transmitter further comprises a conductive pad disposed on the light-emitting surface, and the drive chip is connected to the conductive pad via a wire.
